(19) United States
(12) Patent Application Publication
(10) Pub. No.: US 2012/0175158 A1
(43) Pub. Date: Jul. 12, 2012

(54) CIRCUIT BOARD

(75) Inventor: Taiji OGAWA, Sakura-shi (JP)

(73) Assignee: FUJIKURA LTD., Tokyo (JP)

(21) Appl. No.: 13/427,328

(22) Filed: Mar. 22, 2012

Related U.S. Application Data
(63) Continuation of application No. PCT/JP2010/059534, filed on Jun. 4, 2010.

(30) Foreign Application Priority Data
Oct. 6, 2009 (JP) 2009-232559

(51) Int. Cl. H05K 1/09; H05K 1/00

(52) U.S. Cl. 174/257; 174/250

(57) ABSTRACT

A circuit board 1 comprises: an insulating substrate 10; and electric circuit patterns 20 formed on the insulating substrate 10. Each electric circuit pattern 20 has: a mounting pad section 30; and a wiring section 40 extending from the mounting pad section 30. The mounting pad section 30 has a first nonparallel surface 32a inclined to or substantially orthogonally intersecting a main surface 41 of the wiring section 40.

The present application claims priority from Japanese Patent Application No. 2009-232559 filed on Oct. 6, 2009 and International Application PCT/JP2010/59534 filed on Jun. 4, 2010. The contents described and/or illustrated in the documents relevant to the Japanese Patent Application No. 2009-232559 and International Application PCT/JP2010/59534 will be incorporated herein by reference as a part of the description and/or drawings of the present application.

### TECHNICAL FIELD OF THE INVENTION

The present disclosure relates to a circuit board onto which electronic components, such as BGA (Ball Grid Array) or CSP (Chip Size Package), having solder balls are to be surface mounted.

### DESCRIPTION OF THE RELATED ART

A circuit board is known on which land areas for solder connecting is formed in order to mount electronic components (refer to Patent Document 1, for example).

### PRIOR ART DOCUMENT(S)

### Patent Document(s)

[Patent Document 1] Japanese unexamined Patent Publication No. 2006-120677

### SUMMARY OF THE INVENTION

### Problems to be Solved by the Invention

Incidentally, with reduced size of electronic components in recent years, narrowing and downsizing the land areas have been advanced, and the connecting areas between the land areas and solder thus tend to be reduced.

The land areas are flat in the above circuit board, and therefore, if shrinkage differences are generated between the circuit board and electronic components, then stress is concentrated at solder connections for connecting the land areas with the electronic components, thereby possibly causing cracks.

Problems to be solved by the present invention include providing a circuit board capable of improving the reliability of the solder connections.

### Means for solving the problems

(1) A circuit board according to the present invention comprises: an insulating substrate; and an electric circuit pattern formed on the insulating substrate, the electric circuit pattern has: a mounting pad section; and a wiring section extending from the mounting pad section, and the mounting pad section has a first nonparallel surface inclined to or substantially orthogonally intersecting a main surface of the wiring section.

(2) In the above invention, the mounting pad section may have a concave area surrounded by the first nonparallel surface.

(3) In the above invention, the mounting pad section may have a convex area surrounded by the first nonparallel surface which is inclined to the main surface of the wiring section.

(4) In the above invention, the electric circuit pattern may have a gold plated layer formed on a surface of the mounting pad section.

(5) In the above invention, the gold plated layer may have a second nonparallel surface inclined to or substantially orthogonally intersecting the main surface of the wiring section.

(6) In the above invention, the circuit board may further comprise an electronic component connected with the mounting pad section via a solder ball, and an end of an interface between the solder ball and the mounting pad section may be inclined to or substantially orthogonally intersecting the main surface of the wiring section.

(7) In the above invention, the circuit board may further comprise an electronic component connected with the mounting pad section via a bump, and the bump may comprise gold.

### Advantageous Effect of the Invention

According to the present invention, the mounting pad section has the first nonparallel surface inclined to or substantially orthogonally intersecting the main surface of the wiring section, so that the reliability of the solder connections is improved.

### BRIEF DESCRIPTION OF DRAWINGS

FIG. 1 is a cross-sectional view of a circuit board in a first embodiment of the present invention;

FIG. 2 is an enlarged cross-sectional view of section II in FIG. 1;

FIG. 3 is a cross-sectional view along line III-III in FIG. 2;

FIG. 4 is an enlarged cross-sectional view of section IV in FIG. 2;

FIG. 5 is a principal part cross-sectional view illustrating a first modified example of the circuit board in the first embodiment of the present invention;

FIG. 6 is a principal part cross-sectional view illustrating a second modified example of the circuit board in the first embodiment of the present invention;

FIG. 7 is a principal part cross-sectional view illustrating a third modified example of the circuit board in the first embodiment of the present invention;

FIG. 8 is a principal part cross-sectional view of a circuit board in a second embodiment of the present invention;

FIG. 9 is an enlarged cross-sectional view of section IX in FIG. 8; and

FIG. 10 is a principal part cross-sectional view illustrating a modified example of the circuit board in the second embodiment of the present invention.

### DESCRIPTION OF THE PREFERRED EMBODIMENT

Hereinafter, embodiments according to the present invention will be described with reference to the drawings.

### First Embodiment

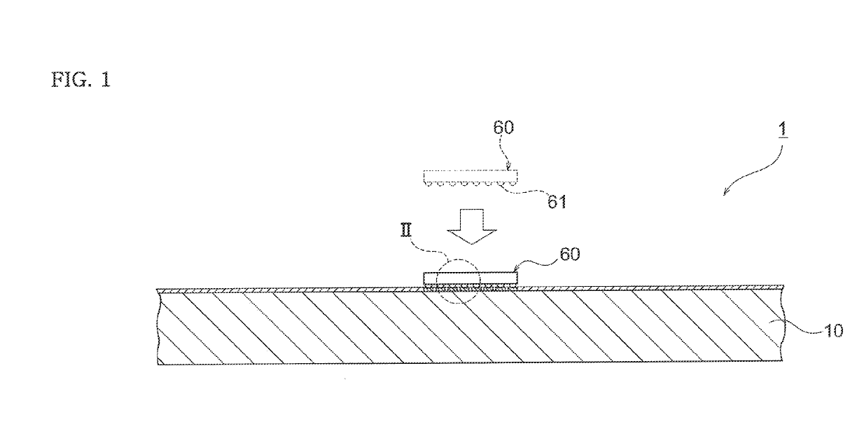

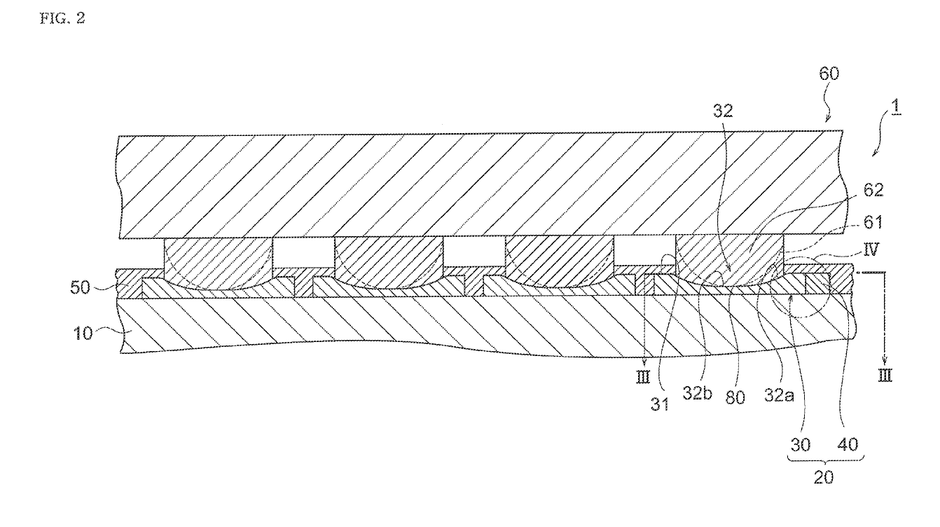

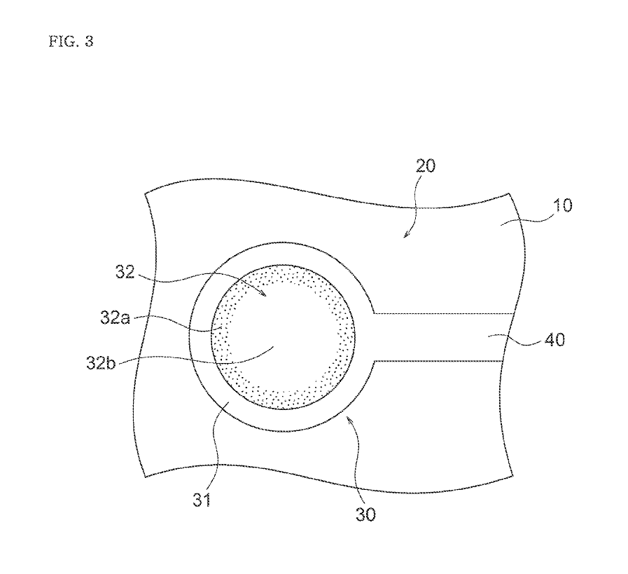

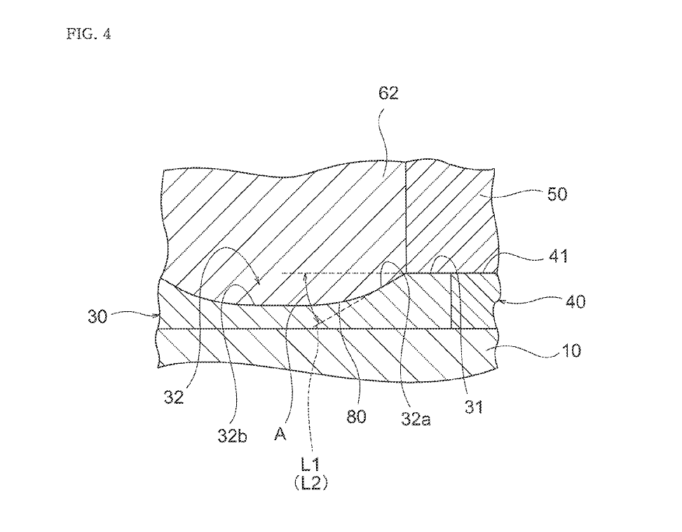

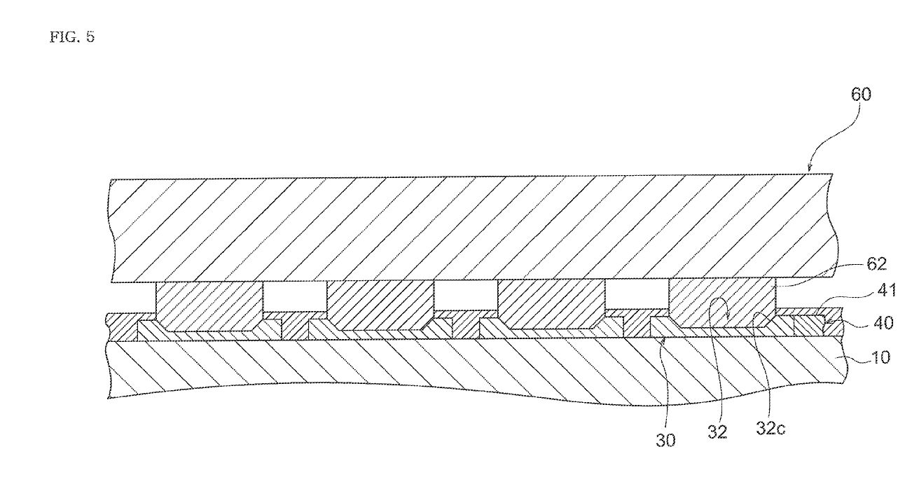

FIG. 1 is a cross-sectional view of a circuit board in the present embodiment, FIG. 2 is an enlarged cross-sectional view of section II in FIG. 1, FIG. 3 is a cross-sectional view along line III-III in FIG. 2, FIG. 4 is an enlarged cross-sectional view of section IV in FIG. 2, and FIG. 5 to FIG. 7 are principal part cross-sectional views illustrating modified examples of the circuit board in the present embodiment.

As shown in FIG. 1, the circuit board 1 in the present embodiment is a circuit board onto which an IC chip (Integrated Circuit chip) 60 is to be mounted by reflow soldering. This circuit board 1 is incorporated in an electronic device, such as a mobile phone.

The IC chip 60 has solder balls 61. The solder balls 61 which are spherically formed out of solder are arranged in a matrix fashion on the lower surface of the IC chip 60.

Here, it is enough that the IC chip 60 is an integrated circuit element provided thereon with solder balls 61. For example, the IC chip 60 may be configured as an IC package, such as ball grid array (BGA) or chip size package (CSP). Alternatively, IC chip 60 may be configured as a die diced from a semiconductor wafer. Note that the IC chip 60 in the present embodiment is equivalent to one example of the electronic component in the present invention.

As shown in FIG. 2, the circuit board 1 comprises: an insulating substrate 10; electric circuit patterns 20 formed on the insulating substrate; and an insulating layer 50. As the circuit board 1, a flexible printed circuit (FPC) board may be mentioned, for example. Note that the circuit board 1 may also be configured as a rigid printed circuit board (PCB).

The insulating substrate 10 is configured of a member having flexibility, such as polyimide. Note that the insulating substrate 10 may also be configured of a member, such as glass-epoxy resin, if the circuit board 1 is a rigid printed circuit board.

The electric circuit patterns 20 are formed on the upper surface of this insulating substrate 10. Each of the electric circuit patterns 20 has a mounting pad section 30 and a wiring section 40 extending from the mounting pad section 30.

As shown in FIG. 2 and FIG. 3, the mounting pad section 30 is of a circular pattern, which is composed of copper, for example. Alternatively, the mounting pad section 30 may be composed of gold, silver, carbon, etc.

The mounting pad section 30 has a flange surface 31 and a concave area 32. The flange surface 31 is an outer circumference area of the upper surface of the mounting pad section 30. Although the flange surface 31 is of annular-like in the present embodiment, the shape thereof is not particularly limited to this. This flange surface 31 is covered by the insulating layer 50 (as will be described later).

The concave area 32 is a concaved part at an inner side of the flange surface 31 within the upper surface of the mounting pad section 30. This concave area 32 is exposed from the insulating layer 50 and connected with a solder connection 62. This concave area 32 has a first nonparallel surface 32a and a bottom surface 32b.

The first nonparallel surface 32a of the concave area 32 is the dotted area in FIG. 3, which is a curved surface (bowl-like shape) falling inward from the inner circumference of the flange surface 31. As shown in FIG. 4, the tangent line L₁ at the end of the first nonparallel surface 32a is inclined at an angle A with respect to the main surface 41 (as will be described later) of the wiring section 40.

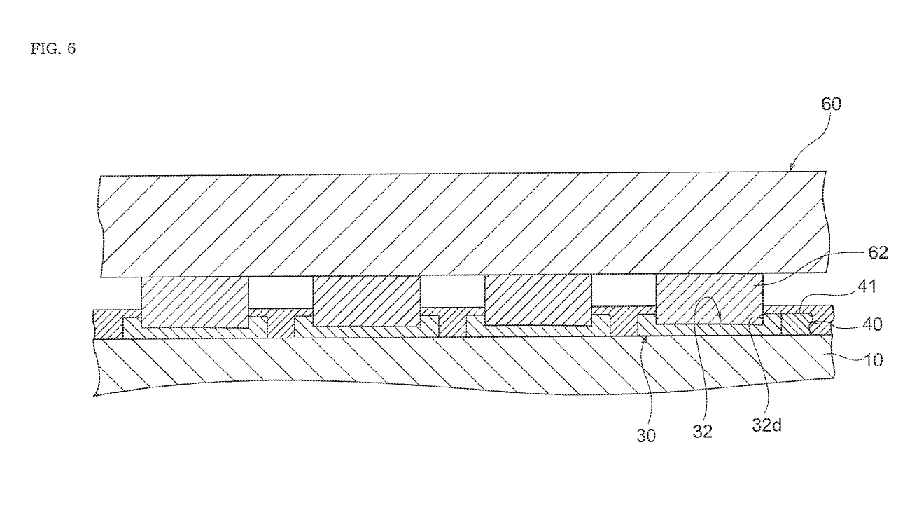

Note that the first nonparallel surface 32a in the present embodiment may not be a curved surface so long as being nonparallel to the main surface 41 of the wiring section 40. For example, as shown in FIG. 5, a first nonparallel surface 32c may be linearly inclined. Moreover, as shown in FIG. 6, a first nonparallel surface 32d may substantially orthogonally intersect the main surface 41 of the wiring section 40.

The bottom surface 32b of the concave area 32 constitutes a bottom area of the concave area 32 and is formed at a level lower than the main surface 41 of the wiring section 40.

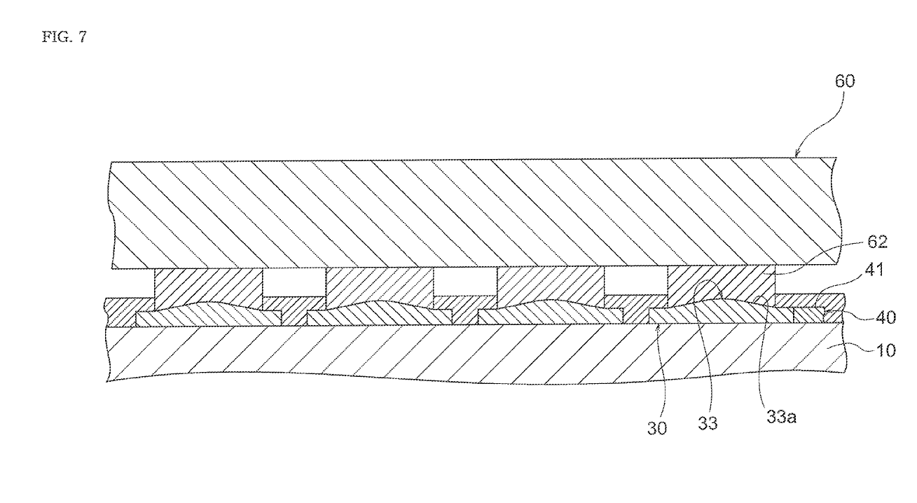

Alternatively, a convex area 33 may be formed on the mounting pad section 30 as a substitute for the concave area 32. This convex area 33 is defined, as shown in FIG. 7, by a first nonparallel surface 33a which is inclined with respect to the main surface 41 of the wiring section 40 so as to uprise inward.

The wiring section 40 is a line extending from the mounting pad section 30, and the main surface 41 thereof is flat. This wiring section 40 is composed of copper, for example. Alternatively, the wiring section 40 may be composed of gold, silver, carbon, etc.

The insulating layer 50 is laminated on the insulating substrate 10 and the electric circuit patterns 20 in the status where the concave area 32 of the mounting pad section 30 is exposed. This insulating layer 50 is formed by screen-printing solder resist in the form of ultraviolet curable acrylic type resin or epoxy type resin, for example. Note that the insulating layer 50 may also be formed by screen-printing solder resist in the form of heat curable epoxy type resin. Further note that the insulating layer 50 may be formed by a dry film solder resist in the form of ultraviolet curable acrylic type resin or epoxy type resin.

A method of manufacturing the above circuit board 1 will then be described.

First, the circular patterns of the mounting pad sections 30 and the wiring sections 40 are formed at the same time by etching a copper foil laminated on the insulating substrate 10. Alternatively, the circular patterns of the mounting pad sections 30 and the wiring sections 40 may be formed at the same time by screen-printing gold paste, silver paste, copper paste, or carbon paste.

Subsequently, ultraviolet curable solder resist is applied and exposed in the status where portions for forming the concave areas 32 of the mounting pad sections 30 are masked, then the solder resist is removed from the portions for forming the concave areas 32 by performing image development, thereby forming the insulating layer 50.

Thereafter, the concave areas 32 are formed by etching the mounting pad sections 30 using chemicals having metal corrosive properties. Note that the depth to be etched at the mounting pad sections 30 is a depth which is sufficient for forming the first nonparallel surfaces 32a in the concave areas 32 and which is not to provide insufficient mechanical strength of the mounting pad sections 30 in themselves, such as within a range from 2 μm to 10 μm.

The above-described circuit board 1 is connected therewith the IC chip 60 by the solder connections 62. These solder connections 62 are pillar-like solders obtained by melting and then solidifying the solder balls 61 during the surface mounting of the IC chip 60. Note that dashed lines shown in FIG. 2 indicate the solder balls 61 before melting, and the pillar-like solders after melting and solidifying are indicated by solid lines in FIG. 2. The solder connections 62 are connected at upper ends thereof with the IC chip 60 and at lower ends thereof with the concave areas 32 of the mounting pad sections 30.

As shown in FIG. 4, dissimilar metal interfaces 80 of solder/copper are formed between the solder connections 62 and the mounting pad sections 30. Here, each dissimilar metal interface 80 is a three-dimensional curved surface along the shape of the concave area 32, and the tangent line L₂ at the end thereof is inclined at the angle A with respect to the main surface 41 of the wiring section 40 likewise the tangent line L₁ at the end of the first nonparallel surface 32a. Note that the dissimilar metal interface 80 is equivalent to one example of the interface in the present invention.

The action in the present embodiment will then be described.

In a cooling step after a reflow soldering step during surface mounting the IC chip 60 on the circuit board 1, shrinkage difference occurs between the circuit board 1 and the IC chip 60. Moreover, such shrinkage difference between the circuit board 1 and the IC chip 60 comes to be more significant as the reflow temperature increases due to employing lead-free solder in recent years.

On the other hand, in the present embodiment, each mounting pad section 30 is formed therein with the first nonparallel surface 32a inclined to the main surface 41 of the wiring section 40, thereby also inclining the dissimilar metal interface 80. In particular, the tangent line L₂ at the end of the dissimilar metal interface 80 is inclined at the angle A, thereby being shifted or deviated from the direction of the stress caused by that shrinkage difference. Consequently, the dissimilar metal interface 80 is enhanced for that stress thereby to suppress the occurrence of cracks in the solder connection 62 and also improve the reliability of the solder connection 62.

Furthermore, in the present embodiment, each mounting pad section 30 is formed therein with the concave area 32 thereby to increase the contact area with the solder connection 62. Consequently, the solder connection 62 is enhanced for that stress because the area of the dissimilar metal interface 80 where the stress concentrates is increased. Therefore, the occurrence of cracks in the solder connection 62 is suppressed and the reliability of the solder connection 62 is improved.

### Second Embodiment

The second embodiment will then be described.

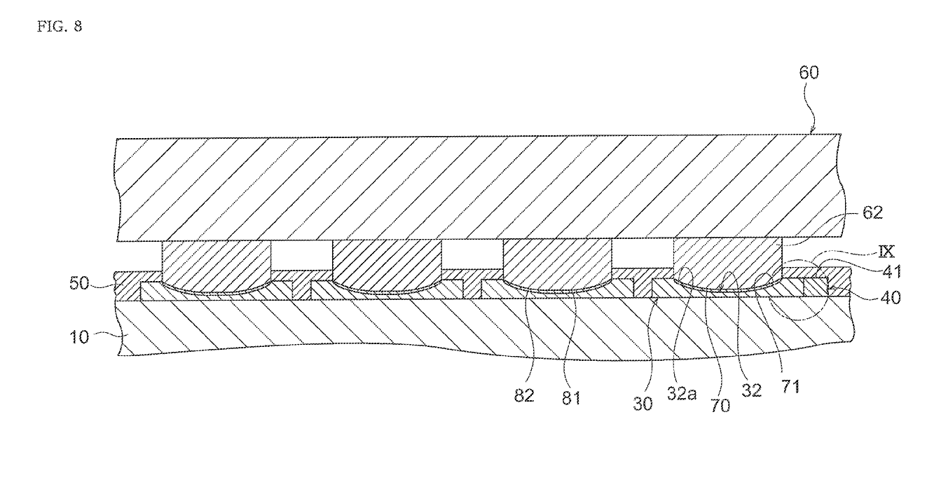

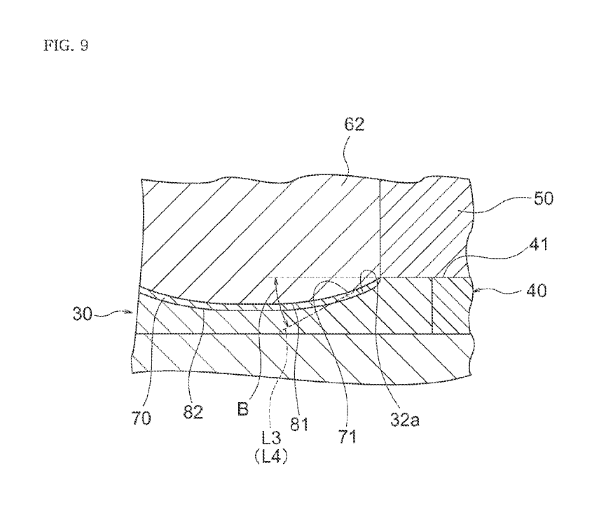

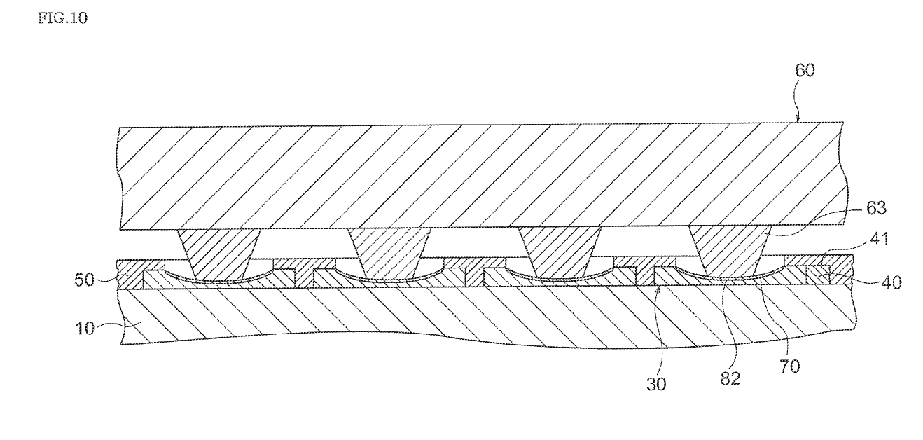

FIG. 8 is a principal part cross-sectional view of a wiring board in the present embodiment, FIG. 9 is an enlarged cross-sectional view of section IX in FIG. 8, and FIG. 10 is a principal part cross-sectional view illustrating a modified example of the wiring board in the present embodiment.

While the present embodiment differs from the first embodiment in the point that gold plated layers 70 are provided, the remaining configuration is similar to the first embodiment. Hereinafter, the difference from the first embodiment will only be described, and components having similar configuration to the first embodiment will be omitted to be described by denoting the same reference numerals.

As shown in FIG. 8, each gold plated layer 70 is deposited above the concave area 32 of the mounting pad section 30 in the status of being exposed from the insulating layer 50. The gold plated layer 70 is provided for improving the wettability with solder and preventing the mounting pad section 30 from oxidization. If the convex area 33 (refer to FIG. 7) is formed within the mounting pad section 30 as a substitute for the concave area 32, then the gold plated layer may be deposited on this convex area 33.

Here, the depth of the concave area 32 within the mounting pad section 30 is set to be larger (e.g. 2 μm to 10 μm) than the thickness of the gold plated layer 70, and the gold plated layer 70 has a shape which follows the shape of the concave area 32. Therefore, the gold plated layer 70 is sterically formed and has a second nonparallel surface 71 inclined likewise the first nonparallel surface 32a.

The second nonparallel surface 71 is an outer circumference area of the upper surface of the gold plated layer 70 and positioned above the first nonparallel surface 32a. As shown in FIG. 9, the tangent line L₃ at the end of the second nonparallel surface 71 is inclined at an angle B with respect to the main surface 41 of the wiring section 40.

This gold plated layer 70 is connected at the upper surface thereof with the solder connection 62, and a dissimilar metal interfaces 81 of gold/solder is formed between the gold plated layer 70 and the solder connection 62. The dissimilar metal interface 81 at the solder connection 62 has a steric shape along the gold plated layer 70, and the tangent line L₄ at the end thereof is inclined along the second nonparallel surface 71 at the angle B with respect to the main surface 41 of the wiring section 40. Consequently, the end of the dissimilar metal interfaces 81 is nonparallel to the direction of the stress caused by the shrinkage difference between the circuit board 1 and the IC chip 60, thereby being enhanced for that stress. Therefore, the occurrence of cracks in the solder connection 62 is suppressed and the reliability of the solder connection 62 is improved.

Moreover, the gold plated layer 70 is connected at the lower surface thereof with the mounting pad section 30, and a dissimilar metal interface 82 of gold/copper is formed between the gold plated layer 70 and the mounting pad section 30. The dissimilar metal interface 82 at the gold plated layer 70 has a three-dimensional shape along the concave area 32, and the tangent line (not shown) at the end thereof is inclined along the first nonparallel surface 32a at the angle A with respect to the main surface 41 of the wiring section 40. Consequently, the end of the dissimilar metal interfaces 82 at the gold plated layer 70 is nonparallel to the direction of the stress caused by the shrinkage difference between the circuit board 1 and the IC chip 60, thereby being enhanced for that stress. Therefore, the occurrence of cracks in the gold plated layer 70 is suppressed, and the reliability of the connection between the IC chip 60 and the mounting pad section 30 is improved.

Furthermore, as shown in FIG. 10, Au (gold) bumps 63 may be formed on the lower surface of the IC chip 60 as a substitute for the solder balls 61. In this case, the Au bumps 63 and the gold plated layers 70 are bonded with one another by ultrasonic bonding. The Au bumps 63 and the gold plated layers 70 are composed of the same kind of metal, and therefore the interfaces between the Au bumps 63 and the gold plated layers 70 are tightly bonded thereby being enhanced for the stress.

For this reason, the stress caused by the shrinkage difference between the circuit board 1 and the IC chip 60 is concentrated at the dissimilar metal interfaces 82. According to the present embodiment, however, the ends of the dissimilar metal interfaces 82 are inclined to the main surfaces 41 of the wiring sections 40, so that the dissimilar metal interfaces 82 at the gold plated layers 70 are enhanced for the stress caused by the shrinkage difference between the circuit board 1 and the IC chip 60. Therefore, the occurrence of cracks in the gold plated layers 70 is suppressed, and the reliability of the connection between the IC chip 60 and the mounting pad sections 30 is improved.

### DESCRIPTION OF REFERENCE NUMERALS

1 . . . circuit board
10 . . . insulating substrate
20 . . . electric circuit pattern
30 . . . mounting pad section
31 . . . flange surface
32 . . . concave area
32a, 32c . . . first nonparallel surface
32b . . . bottom surface
33 . . . convex area
33a . . . first nonparallel surface
40 . . . wiring section
41 . . . main surface
50 . . . insulating layer
60 . . . IC chip
61 . . . solder ball
62 . . . solder connection
63 . . . Au bump
70 . . . gold plated layer
71 . . . second nonparallel surface
80, 81, 82 . . . dissimilar metal interface

What is claimed is:

1. A circuit board comprising:
an insulating substrate; and
an electric circuit pattern formed on the insulating substrate, wherein the electric circuit pattern has:
a mounting pad section; and
a wiring section extending from the mounting pad section, and
the mounting pad section has a first nonparallel surface inclined to or substantially orthogonally intersecting a main surface of the wiring section.

2. The circuit board as set forth in claim 1, wherein
the mounting pad section has a concave area surrounded by the first nonparallel surface.

3. The circuit board as set forth in claim 2, wherein
the electric circuit pattern has a gold plated layer formed on a surface of the mounting pad section.

4. The circuit board as set forth in claim 3, wherein
the gold plated layer has a second nonparallel surface inclined to or substantially orthogonally intersecting the main surface of the wiring section.

5. The circuit board as set forth in claim 3, further comprising an electronic component connected with the mounting pad section via a bump, wherein
the bump comprises gold.

6. The circuit board as set forth in claim 1, wherein
the mounting pad section has a convex area surrounded by the first nonparallel surface, the first nonparallel surface being inclined to the main surface of the wiring section.

7. The circuit board as set forth in claim 6, wherein
the electric circuit pattern has a gold plated layer formed on a surface of the mounting pad section.

8. The circuit board as set forth in claim 7, wherein
the gold plated layer has a second nonparallel surface inclined to or substantially orthogonally intersecting the main surface of the wiring section.

9. The circuit board as set forth in claim 7, further comprising an electronic component connected with the mounting pad section via a bump, wherein
the bump comprises gold.

10. The circuit board as set forth in claim 1, further comprising an electronic component connected with the mounting pad section via a solder ball, wherein
an end of an interface between the solder ball and the mounting pad section is inclined to or substantially orthogonally intersecting the main surface of the wiring section.
